(19) United States
(12) Patent Application Publication
(10) Pub. No.: US 2017/0276735 A1
(43) Pub. Date: Sep. 28, 2017

(54) METHOD FOR MANUFACTURING DISPLACEMENT DETECTION SENSOR FOR SEALED-TYPE SECONDARY BATTERY

(71) Applicant: TOYO TIRE & RUBBER CO., LTD., Osaka-shi, Osaka (JP)

(72) Inventors: Takeshi Fukuda, Osaka-shi (JP); Toshiaki Kawai, Osaka-shi (JP)

(73) Assignee: TOYO TIRE & RUBBER CO., LTD., Osaka-shi, Osaka (JP)

(21) Appl. No.: 15/510,759

(22) PCT Filed: Aug. 4, 2015
(86) PCT No.: PCT/JP2015/072029

§ 371 Date: Mar. 13, 2017

(30) Foreign Application Priority Data
Nov. 20, 2014 (JP) 2014-235473

(51) Int. Cl. G01R 31/36; B29C 35/02; H01M 2/10; B29C 45/00; H01M 10/0525; H01M 10/48

(52) U.S. Cl. CPC G01R 31/3679; G01R 31/3606; H01M 10/0525; H01M 10/482; H01M 2/1077; B29C 45/0013; B29C 35/02; H01M 2220/20; B29L 2031/34

(57) ABSTRACT

A method for manufacturing a displacement detection sensor that is for a sealed-type secondary battery and comprises a polymer matrix layer and a detection unit;

the polymer matrix layer comprising a filler which is in a dispersed state and which changes an external field in response to a displacement of the polymer matrix layer, and the detection unit being a unit for detecting a change of the external field; and

the method comprising:

a first step of mixing the filler with a polymer matrix precursor to prepare a mixture liquid,

a second step of injecting the mixture liquid into a container having a predetermined shape, and

a third step of heating and curing the polymer matrix precursor in the container to produce the polymer matrix layer integrated with the container.

### TECHNICAL FIELD

The present invention relates to a method for manufacturing a sensor for detecting a displacement of a sealed-type secondary battery; a sensor that is manufactured by this manufacturing method and detects a displacement of a sealed-type secondary battery; a sealed-type secondary battery to which this sensor is fitted; and a method for detecting a displacement of this sealed-type secondary battery.

### BACKGROUND ART

In recent years, a sealed-type secondary battery (hereinafter sometimes referred to merely as a “secondary battery”), a typical example thereof being a lithium ion secondary battery, has been used not only in any mobile instruments such as a portable telephone or book-size personal computer, but also as a power source for any electric motor car such as an electric vehicle or a hybrid car. Single batteries (cells) constituting a secondary battery each have a group of electrodes that is obtained by winding or stacking a positive electrode and a negative electrode onto each other to interpose a separator therebetween, and an external packaging body in which the electrode group is held. In general, a laminated film, or a metallic can is used as the external packaging body, and the electrode group is held, together with an electrolytic solution, in a sealed space in the external packaging body.

A secondary battery is used in the form of a battery module or battery pack including a single cell or plural cells in an article for which a high-voltage is required, such as a power source for the above-mentioned electric motor car. In such a battery module, plural cells connected in series to each other are held in a package. For example, four cells are connected to each other in the form of two parallel-form-connected lines each made of two-serially-connected-ones of the four cells, or in series of the four cells. In such a battery pack, various devices such as a controller, together with plural battery modules connected in series to each other, are held in a package. In a secondary battery used in a power source for an electric motor car, a package for its battery pack is made into a shape suitable for being mounted into a vehicle.

Such a secondary battery has the following problem: when its electrolytic solution is decomposed by overcharge or some other, a decomposition gas therefrom raises the pressure inside the secondary battery; and with the raise, its cells swell so that the secondary battery is displaced. In this case, when the charging current or the discharge current is not stopped, the secondary battery ignites. As a worse result, the secondary battery is caused to burst. It is therefore important for a prevention of the bursting of any secondary battery to detect, with a high sensitivity, a displacement of the secondary battery on the basis of a swelling of its cells in such a manner that a charging current therefor or discharge current therefrom can be stopped at an appropriate time.

Patent Document 1 describes a device for monitoring a secondary battery in which a pressure sensor is located in an inner space of a safety valve to monitor the pressure in the battery. In this patent document, details of the pressure sensor for monitoring the pressure are unclear. In general, however, an electrical pressure sensor is used. In this case, electrical wire from inside the battery is required; thus, it is feared that the battery is lowered in sealing degree.

Patent Document 2 describes an internal pressure detecting system in which a pressure-sensitive electroconductive rubber that changes continuously in resistance value is located inside a battery case. However, according to the system described in this patent document, it is indispensable to lead wiring for detecting a change in the resistance to the outside of a sealed-type battery. Thus, it is feared that the battery is lowered in sealing degree.

Furthermore, Patent Document 3 describes a battery cell in a laminated-type battery, this cell being a cell having a formed internal gas pressure detection unit in which inside-resin-layers of laminated films are not present in a portion of a melt-bonded part of the battery so that metal layers contact each other to turn into an electroconductive state. However, in the laminated-type battery described in this patent document, the metal layers are naked to contact any other member, thereby being easily short-circuited therebetween. Furthermore, its laminate pack is peeled away with time to cause a trouble of the battery cell easily.

### PRIOR ART DOCUMENTS

### Patent Documents

Patent Document 1: JP-A-2002-289265
Patent Document 2: JP-A-2001-345123
Patent Document 3: JP-A-2009-245879

### SUMMARY OF THE INVENTION

### Problems to be Solved by the Invention

About a sensor for detecting a displacement of a secondary battery, it is required to make the size thereof small not to press the secondary battery into a small volume. Additionally, the sensor needs to be fitted to an arbitrarily-selected shape of, for example, an empty volume space in the secondary battery. In the actual situation, therefore, the market requires displacement detection sensors to be each manufactured into any shape with excellent property stability.

In light of the actual situation, the present invention has been made, and an object thereof is to provide a method for manufacturing a displacement detection sensor which can be located, with any shape, into a sealed-type secondary battery and which is excellent in property stability; a displacement detection sensor that is for a sealed-type secondary battery and that is manufactured by this manufacturing method; a sealed-type secondary battery to which this sensor is fitted; and a method for detecting a displacement of this sealed-type secondary battery.

### Means for Solving the Problems

The above-mentioned object can be attained by the present invention, which is described hereinafter. Accordingly, the invention relates to a method for manufacturing a displacement detection sensor that is for a sealed-type secondary battery and comprises a polymer matrix layer and a detection unit; and the polymer matrix layer comprises a filler which is in a dispersed state and which changes an external field in response to a displacement of the polymer matrix layer, and the detect ion unit being a unit for detecting a change of the external field. Furthermore, this method comprises a first step of mixing the filler with a polymer matrix precursor to prepare a mixture liquid, a second step of injecting the mixture liquid into a container having a predetermined shape, and a third step of heating and curing the polymer matrix precursor in the container to produce the polymer matrix layer integrated with the container.

For example, between any adjacent two cells of the battery, the polymer matrix layer is fitted to the battery to be sandwiched between any one of the cells and a package holding the cell. Alternatively, the polymer matrix layer is fitted to the battery to be sandwiched between a package for a battery module included in a pack of the battery and a package for a battery module adjacent to the former battery module; and is further fitted to the battery to be sandwiched in a gap between the packages for the battery modules, and a package for the battery pack. In any one of these cases, the polymer matrix layer may be fitted thereto in the state of being compressed.

When the secondary battery is displaced by a swelling of its cells, the polymer matrix layer is displaced accordingly. The detection unit detects an external field change which follows the displacement of the polymer matrix layer. In this way, the displacement of the secondary battery is detectable with a high sensitivity. The polymer matrix layer fitted as described above does not press the secondary battery into a small volume, and further this layer is restrained from being shifted out of position by vibration or some other. As a result, properties of the sensor are made stable.

The polymer matrix layer is produced through a production process including at least the first step of mixing a filler with a polymer matrix precursor to prepare a mixture liquid, the second step of injecting the mixture liquid into a container having a predetermined shape, and the third step of heating and curing the polymer matrix precursor in the container to produce the polymer matrix layer integrated with the container. In other words, the polymer matrix layer is produced inside the container having the predetermined shape; therefore, the manufacturing method according to the present invention makes it possible to manufacture a displacement detection sensor that is for a sealed-type secondary battery and that has the polymer matrix layer, which has a desired shape corresponding to a location spot inside or outside the sealed-type secondary battery.

In the method according to the present invention for manufacturing a displacement detection sensor for a sealed-type secondary battery, it is preferred that the polymer matrix layer comprises a magnetic filler as the filler, the detection unit is a unit for detecting a change of a magnetic field as the external field, and the third step comprises a magnetizing step of heating and curing the polymer matrix precursor in the container, and subsequently magnetizing the magnetic filler. This embodiment makes it possible to detect a change of the magnetic field which follows the displacement of the polymer matrix layer without using wiring. Moreover, this embodiment makes it possible to use a Hall element, which is wide in sensitivity range, as the detection unit to manufacture a displacement detection sensor that can attain detection with a high sensitivity over a wider range.

In this method, for manufacturing a displacement detection sensor for a sealed-type secondary battery, it is preferred that the container comprises a sealing material. As described above, when an electrolytic solution inside the sealed-type secondary battery is decomposed by, e.g., overcharge, the electrolytic solution may leak to, e.g., the outside of the battery to contact the displacement detection sensor. In such a case, when the polymer matrix layer of the displacement detection sensor is immersed in the electrolytic solution to suffer from a displacement, breaking or some other, it may become difficult to detect a displacement of the secondary battery precisely. However, when the polymer matrix layer, which the displacement detection sensor for the sealed-type secondary battery has, is produced inside a sealing material having a predetermined shape, the polymer matrix layer can be produced into a desired shape and further the polymer matrix layer (i.e., the displacement detection sensor) can be improved in electrolytic solution resistance.

In the present invention, the sealed-type secondary battery, to which the displacement detection sensor having the polymer matrix layer and the detection unit is fitted, particularly has at least one cell having the following: an electrode group obtained by winding or stacking a positive electrode and a negative electrode to interpose a separator therebetween; and an external packaging body in which the electrode group is held. Thus, even in a case where the polymer matrix layer is located inside the cell, a displacement of the cell can be favorably sensed with a high precision, without swelling this layer into the electrolytic solution, when the polymer matrix layer is produced inside the container made of the sealing material.

In this method for manufacturing a displacement detection sensor for a sealed-type secondary battery, the container preferably has a shape about which the length (a) of its upper surface is equal to or longer than the length (b) of its lower surface, and the expression “1≦(a)/(b)≦2” is preferably satisfied. In the case of injecting the mixture liquid containing the polymer matrix precursor into the container having the predetermined shape, unless the mixture liquid is injected into the container without generating any dead air space or the like, a defect is generated in the produced polymer matrix layer in accordance with the size of the resultant dead air space. As a result, the function of the sensor may not be sufficiently exhibited. However, by rendering the shape of the used container a shape about which the length (a) of its upper surface is equal to or longer than the length (b) of its lower surface, particularly, by causing the shape to satisfy “1≦(a)/(b)≦2”, the mixture liquid can be injected into the container without generating any dead air space or the like even when the mixture liquid containing the filler and the polymer matrix precursor is relatively high in viscosity. As a result, the displacement detection sensor for a sealed-type secondary battery can be produced with a sensor function that can be effectively exhibited.

The displacement detection sensor according to the present invention for a sealed-type secondary battery is a sensor manufactured by the above-mentioned manufacturing method. This displacement detection sensor for a sealed-type secondary battery can be located with any shape in the sealed-type secondary battery.

The sealed-type secondary battery according to the present invention is a battery to which the above-mentioned displacement detection sensor is fitted. The form thereof may be a single battery module, or may be a battery pack including plural battery modules. In this sealed-type secondary battery, a displacement thereof on the basis of a swelling of its cell is detected with a high sensitivity through the displacement detection sensor. In addition, the displacement detection sensor does not press the secondary battery into a small volume, so that sensor properties thereof are stable.

The method according to the present invention for detecting a displacement of a sealed-type secondary battery is a method in which: a polymer matrix layer is set into the sealed-type secondary battery, or is set to the sealed-type secondary battery to contact the secondary battery; and the polymer matrix layer is a layer that comprises a filler which is in a dispersed state and which changes an external field in response to a displacement of the polymer matrix layer, and that is manufactured through at least a first step of mixing the filler with a polymer matrix precursor to prepare a mixture liquid, a second step of injecting the mixture liquid into a container having a predetermined shape, and a third step of heating and curing the polymer matrix precursor in the container to produce the polymer matrix layer integrated with the container. This method is further a method of detecting the change of the external field, which follows the displacement of the polymer matrix layer, and then detecting the displacement of the sealed-type secondary battery, the battery module and/or the battery pack on the basis of the change of the external field. It is preferred that, in particular, the polymer matrix layer comprises a magnetic filler as the filler, and that the third step comprises a magnetizing step of heating and curing the polymer matrix precursor in the container, and subsequently magnetizing the magnetic filler.

The polymer matrix layer is set into the sealed-type secondary battery; or is set into, for example, a gap which the sealed-type secondary battery has, so as to contact the sealed-type secondary battery. When the secondary battery is displaced by a swelling of its cell, the polymer matrix layer is displaced accordingly. By detecting a change of an external field which follows the displacement of the polymer matrix layer, a displacement of the secondary battery can be detected with a high sensitivity. In the present invention, particularly, the polymer matrix layer integrated with the container is produced; thus, a displacement of the sealed-type secondary battery that may have various shapes can be detected. In order to enhance this function further, it is preferred that the polymer matrix layer comprises a magnetic filler as the filler, and the detection unit is a unit which detects a change of a magnetic field as the external field.

### BRIEF DESCRIPTION OF THE DRAWINGS

FIG. 1 is a perspective view illustrating an example of a battery module schematically.

FIG. 2 is a sectional view illustrating the module on line A-A in FIG. 1 schematically when the module is viewed in an arrow direction.

FIG. 3 is a sectional view illustrating a different example of a site of a battery to which a polymer matrix layer is bonded.

FIG. 4 is a sectional view illustrating an example of a polymeric matrix layer integrated with a container.

### MODE FOR CARRYING OUT THE INVENTION

Hereinafter, an embodiment of the present invention will be described.

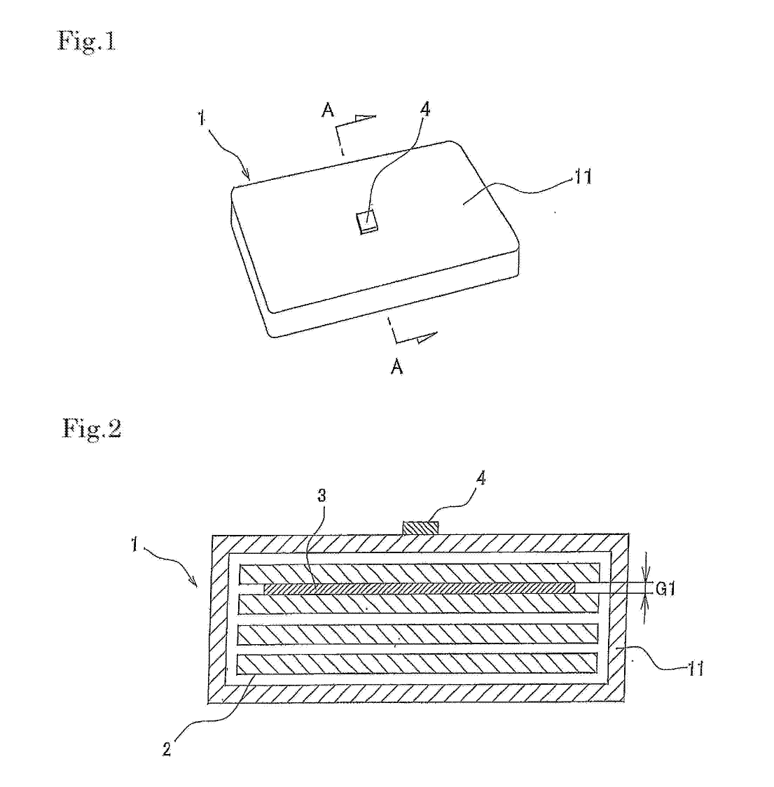

A battery module 1 illustrated in FIGS. 1 and 2 has, inside its package 11, plural cells 2. In the present embodiment, the cells, the number of which is four, are connected in series to each other (for example, in the form of two parallel-form-connected lines each made of two-serially-connected-ones of the four cells, or in series of the four cells). The cells 2 each have a group of electrodes which is produced by winding or stacking a positive electrode and a negative electrode onto each other to interpose a separator therebetween, and an external packaging body in which the electrode group is held, this situation being illustrated in detail. In a sealed space of the inside of the external packaging body, the electrode group is held together with an electrolytic solution. For the external packaging body of each of the cells 2, a laminated film, such as an aluminum laminated foil piece, is used. Instead of this film, however, a cylindrical type or rectangular type metallic can may be used.

This battery module 1 is a lithium ion secondary battery usable as a power source for electric motor cars. Such battery modules are made in the form of a battery pack to be mounted into a car. The battery module 1 and the same battery module(s) 1 connected in series to each other are held, together with various devices such as a controller, in a package. The package for the battery pack is made into a shape suitable for being mounted into the car, for example, a shape matched with the shape of a space below the floor of the car. In the present invention, the sealed-type secondary battery is not limited to any non-aqueous electrolytic solution secondary battery such as a lithium ion battery, and may be an aqueous electrolytic solution secondary battery such as a nickel-hydrogen battery.

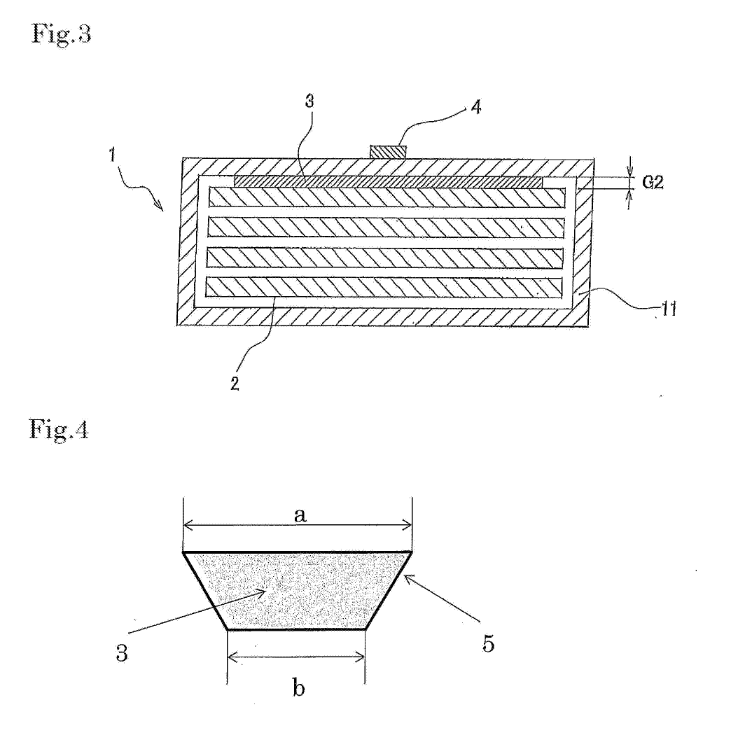

As illustrated in FIG. 2, a displacement detection sensor is fitted to the sealed-type secondary battery. The displacement detection sensor has a polymer matrix layer 3 and a detection unit 4. The detection unit 4 is bonded onto a surface of the cells 2 (outer surface of an external packaging body therefor). For the bonding, an adhesive or an adhesive tape is used as needed. Inside a container having a predetermined shape, the polymer matrix layer 3 is made into, e.g., a sheet form, and is located in a gap in the secondary battery, for example, a gap between adjacent two of the cells 2; or as illustrated in FIG. 3, the layer 3 is located between one of the cells 2, and the package 11 in which the cells 2 are held. The polymer matrix layer 3 may be bent to be bonded to a corner of any one of the cells 2, or a corner of the package 11.

The polymer matrix layer 3 contains a filler dispersed in this layer and giving a change to an external field in response to a displacement of the polymer matrix layer 3. The detection unit 4 detects the change of the external field. The detection unit 4 is arranged apart from the polymer matrix layer 3 to such an extent that the change of the external field is detectable, and this unit is preferably bonded to a site of the battery which is relatively strong not to receive an effect of a swell of the cells 2 easily. In the present embodiment, the detection unit 4 is bonded to an outer surface of the package 11. However, the present invention is not limited into this form. Thus, the detection unit 4 may be bonded to an inner surface of the package 11 or a package for the battery pack. Such a package is made of, e.g., a metal or plastic material. For the package for each of the battery modules, a laminated film may be used.

The polymer matrix layer 3 illustrated in FIG. 2 is fitted into the gap to be sandwiched in a compressed state. The thickness of the polymer matrix layer 3 in a non-compressed state is larger than the gap, which is a gap G1, in which this layer is located. The polymer matrix layer 3 is compressed into the thickness direction. The polymer matrix layer 3 illustrated in FIG. 3 is also fitted into a gap to be sandwiched in a compressed state. In this example, this layer is fitted into the gap between one of the cells 2 and the package 11 to be sandwiched therebetween in a compressed state. The thickness of this polymer matrix layer 3 in a non-compressed state is larger than the gap, which is a gap G2, in which this layer is located. The polymer matrix layer 3 is also compressed into the thickness direction.

When the cells 2 swell, the polymer matrix layer 3 is displaced accordingly. The detection unit 4 detects a change of the external field which follows the displacement of the polymer matrix layer 3. A detection signal outputted from the detection unit 4 is sent to a control unit not illustrated. When it is detected through the detection unit 4 that the external field change is a change showing a set value or more, a switching circuit connected to the control unit and not illustrated cuts off the passage of electric current to stop the charging current or discharge current. In this way, the displacement of the secondary battery, which is based on the swell of the cells 2, is detected with a high sensitivity to prevent the secondary battery from bursting. This displacement detecting sensor does not press the secondary battery into a small volume; thus, the sensor is restrained from being shifted out of position to stabilize properties of the sensor.

In the example in each of FIGS. 2 and 3, the single polymer matrix layer 3 and the single detection unit 4 have been illustrated. However, plural polymer matrix layers and plural detection units may be used in accordance with the shape and size of the secondary battery, and other conditions. At this time, the polymer matrix layer 3 located as illustrated in FIG. 2 and the polymer matrix layer 3 located as illustrated in FIG. 3 may be together located. Furthermore, plural polymer matrix layers 3 may be located to the same single cell 2, or plural detection units 4 may detect a change of the external field which follows a change of the same polymer matrix layer 3.

In the present embodiment, the polymer matrix layer 3 contains a magnetic filler as the above-mentioned filler, and the detection unit 4 detects a change of a magnetic field as the external field, i.e., the amount of a change in the magnetic flux density. In this case, the polymer matrix layer 3 is preferably a magnetic elastomer layer in which a magnetic filler is dispersed in a matrix made of an elastomer component.

Examples of the magnetic filler include rare earth based, iron based, cobalt based, nickel based, and oxide based fillers. The rare earth based fillers, which give a higher magnetic force, are preferred. The shape of the magnetic filler is not particularly limited, and may be any one of the following; spherical, flat, needle, columnar and indeterminate shapes. The average particle diameter of the magnetic filler is preferably from 0.02 to 500 μm, more preferably from 0.1 to 400 μm, even more preferably from 0.5 to 300 μm. If the average particle diameter is less than 0.02 μm, the magnetic filler tends to be lowered in magnetic properties. If the average particle diameter is more than 500 μm, the magnetic elastomer layer tends to be lowered in mechanical properties to become brittle.

In the method according to the present invention for manufacturing a displacement detection sensor for a sealed-type secondary battery, its polymer matrix layer is produced through a production process including a first step of mixing a filler with a polymer matrix precursor to prepare a mixture liquid, a second step of injecting the mixture liquid into a container having a predetermined shape, and a third step of heating and curing the polymer matrix precursor in the container to produce the polymer matrix layer integrated with the container.

As the polymer matrix, for example, an elastomer component is usable. As the elastomer component, any component is usable. The elastomer component may be a thermoplastic elastomer, a thermosetting elastomer, or a mixture of these elastomers. Examples of the thermoplastic elastomer include styrene type, polyolefin type, polyurethane type, polyester type, polyamide type, polybutadiene type, polyisoprene type, and fluorine-contained rubber type thermoplastic elastomers. Examples of the thermosetting elastomer include diene synthetic rubbers such as polyisoprene rubber, polybutadiene rubber, styrene-butadiene rubber, polychloroprene rubber, nitrile rubber and ethylene-propylene rubber; non-diene rubbers such as ethylene-propylene rubber, butyl rubber, acrylic rubber, polyurethane rubber, fluorine-contained rubber, silicone rubber and epichlorohydrin rubber; and natural rubbers. Out of these rubbers, preferred are thermosetting elastomers since the elastomers make it possible to restrain the magnetic elastomer from flowing down in accompaniment with the generation of heat from the battery or an excessive load thereon. More preferred is polyurethane rubber (referred to also as polyurethane elastomer) or silicone rubber (referred to also as silicone elastomer).

The polyurethane elastomer is obtained by causing an active-hydrogen-containing compound to react with an isocyanate component. When the polyurethane elastomer is used as the elastomer component, the active-hydrogen-containing compound and the magnetic filler are mixed with each other and then the isocyanate component is blended into the mixture to yield a mixed liquid. The mixed liquid may be obtained by blending the magnetic filler into the isocyanate component and then blending the active-hydrogen-containing compound into the resultant mixture. Even when either of these methods is used, the magnetic filler is mixed with the polymer matrix precursor containing the active-hydrogen-containing compound and the isocyanate component to prepare the mixture liquid (first step). When a silicone elastomer is used as the elastomer component, the mixture liquid can be prepared by putting the magnetic filler into a precursor of the silicone elastomer to mix these components with each other. As needed, a solvent may be added to the raw materials for the mixture liquid.

An isocyanate component usable for the polyurethane elastomer may be a compound known in the field of polyurethane. Examples thereof include aromatic diisocyanates such as 2,4-toluene diisocyanate, 2,6-toluene diisocyanate, 2,2′-diphenylmethane diisocyanate, 2,4′-diphenylmethane diisocyanate, 4,4′-diphenylmethane diisocyanate, 1,5-naphthaiene diisocyanate, p-phenylene diisocyanate, m-phenylene diisocyanate, p-xylylene diisocyanate and m-xylylene diisocyanate; aliphatic diisocyanates such as ethylene diisocyanate, 2,2,4-trimethylhexamethylene diisocyanate and 1,6-hexamethylene diisocyanate; and alicyclic diisocyanates such as 1,4-cyclohexane diisocyanate, 4,4′-dicyclohexylmethane diisocyanate, isophorone diisocyanate and norbornane diisocyanate. These may be used singly or in the form of a mixture of two or more thereof. The isocyanate component may be a modified component such as a urethane modified, allophanate modified, biuret modified or isocyanurate modified component. The isocyanate component is preferably 2,4-toluene diisocyanate, 2,6-toluene diisocyanate, 4,4′-diphenylmethane diisocyanate, and is more preferably 2,4-toluene diisocyanate, or 2,6-toluene diisocyanate.

In the present invention, the active-hydrogen-containing compound may be a known compound in the field of polyurethane. Examples thereof are polyether polyols, typical examples thereof including polytetramethylene glycol, polypropylene glycol, polyethylene glycol, and any copolymer made from propylene oxide and ethylene oxide; polyester polyols, typical examples thereof including polybutylene adipate, polyethylene adipate, and 3-methyl-1,5-pentane adipate; polyester polycarbonate polyols, examples thereof including reactants each made from a polyester glycol such as polycaprolactone polyol or polycaprolactone, and an alkylene carbonate; polyester polycarbonate polyols each obtained by causing ethylene carbonate to react with a polyhydric alcohol, and next causing the resultant reaction mixture to react with an organic dicarboxylic acid; polycarbonate polyols each obtained by interesterification reaction between a polyhydroxyl compound and an aryl carbonate; and other high-molecular-weight polyols. These may be used singly or in any combination of two or more thereof.

Besides these high-molecular-weight polyol components, the following may be used as the active-hydrogen-containing compound: ethylene glycol, 1,2-propylene glycol, 1,3-propylene glycol, 1,4-butanediol, 1,6-hexanediol, neopentyl glycol, 1,4-cyclohexanedimethanol, 3-methyl-1,5-pentanediol, diethylene glycol, triethylene glycol, 1,4-bis(2-hydroxyethoxy)benzene, trimethylolpropane, glycerin, 1,2,6-hexanetriol, pentaerythritol, tetramethylolcyclohexane, methyl glucoside, sorbitol, mannitol, dulcitol, sucrose, 2,2,6,6-tetrakis(hydroxymethyl)cyclohexanol, triethanolamine, and other low-molecular-weight polyol components; and ethylenediamine, tolylenediamine, diphenylmethanediamine, diethylenetriamine, and other low-molecular-weight polyamine components. These may be used singly or in any combination of two or more thereof. Furthermore, the following may be blended thereinto: 4,4′-methylenebis(o-chloroaniline) (MOCA), 2,6-dichloro-p-phenylenediamine, 4,4′-methylenebis(2,3-dichloroaniline), 3,5-bis(methylthio)-2,4-toluenediamine, 3,5-bis(methylthio)-2,6-toluenediamine, 3,5-diethyltoluene-2,4-diamine, 3,5-diethyltoluene-2,6-diamine, trimethylene glycol-di-p-aminobenzoate, polytetramethylene oxide-di-p-aminobenzoate, 1,2-bis(2-aminophenylthio)ethane, 4,4′-diamino-3,3′-diethyl-5,5′-dimethyldiphenylmethane, N,N′-di-sec-butyl-4,4′-diaminodiphenylmethane, 4,4′-diamino-3,3′-diethyldiphenylmethane, 4,4′-diamino-3,3′-diethyl-5,5′-dimethyldiphenylmethane, 4,4′-diamino-3,3′-diisopropyl-5,5′-dimethyldiphenylmethane, 4,4′-diamino-3,3′,5,5′-tetraethyldiphenylmethane, 4,4′-diamino-3,3′,5,5′-tetraisopropyldiphenylmethane, m-xylylenediamine,-di-sec-butyl-p-phenylenediamine, m-phenylenediamine, p-xylylenediamine, and other polyamines. About the active-hydrogen-containing compound, preferred are polytetramethylene glycol, polypropylene glycol, any copolymer made from propylene oxide and ethylene oxide, 3-methyl-1,5-pentane adipate; and more preferred are polypropylene, and any copolymer made from propylene oxide and ethylene oxide.

When the polyurethane elastomer is used, the NCO index thereof is preferably from 0.3 to 1.2, more preferably from 0.35 to 1.1, even more preferably from 0.4 to 1.05. If the NCO index is less than 0.3, the magnetic elastomer tends to be insufficiently cured. If the NCO index is more than 1.2, the polymer matrix layer becomes high in elastic modulus so that the sensor sensitivity tends to be lowered.

The amount of the magnetic filler in the magnetic elastomer is preferably from 1 to 2000 parts by weight, more preferably from 5 to 1500 parts by weight for 100 parts by weight, of the elastomer component. If this amount is less than 1 part by weight, the sensor tends not to detect a change of the magnetic field easily. If the amount is more than 450 parts by weight, the magnetic elastomer itself may become brittle.

The detection unit 4 for detecting a change of the magnetic field can make use of, for example, a magnetoresistive element, a Hall element, an inductor, an MI element, or a flux gate sensor. Examples of the magnetoresistive element include semiconductor compound magnetoresistive elements, anisotropic magnetoresistive elements (AMRs), giant magnetoresistive elements (GMRs), and tunnel magnetoresistive elements (TMRs). Out of these examples, a Hall element is preferred. This element is useful for the detection unit 4 that is a unit having a high sensitivity in a wide range.

Subsequently to the first step, the mixture liquid obtained in the first step is injected into a container having a predetermined shape (second step). At this time, the container may be completely filled with the mixture solution to cause the polymer matrix layer to constitute the inside of the container completely at last, or the container may not be completely filled with the mixture solution to cause the polymer matrix layer and a cavity layer to constitute the inside of the container at last. Hereinafter, a description will be made about an example in which the mixture liquid obtained in the first step is a mixture liquid obtained by mixing a magnetic filler with a polymer matrix precursor containing an active-hydrogen-containing compound and an isocyanate component, and the container is made of a sealing material. It is preferred that the polymer matrix layer which the displacement detection sensor for a sealed-type secondary battery has is produced inside a sealing material having a predetermined shape since the polymer matrix layer can be produced into a desired shape and further the polymer matrix layer (i.e., the displacement detection sensor) can be improved in electrolytic solution resistance.

The sealing material may be a thermoplastic resin, a thermosetting resin or a mixture of the two resins. Examples of the thermoplastic resin include styrene-, polyolefin-, polyurethane-, polyester-, polyamide-, polybutadiene-, polyisoprene-, and fluororesin-type thermoplastic elastomers; and ethylene/ethyl acrylate copolymer, ethylene/vinyl acetate copolymer, polyvinyl chloride, polyvinylidene chloride, chlorinated polyethylene, fluororesin, polyamide, polyethylene, polypropylene, polyethylene terephthalate, polybutylene terephthalate, polystyrene, and polybutadiene. Examples of the thermosetting resin include diene synthetic rubbers such as polyisoprene rubber, polybutadiene rubber, styrene/butadiene rubber, polychloroprene rubber, and acrylonitrile/butadiene rubber; non-diene rubbers such as ethylene/propylene rubber, ethylene/propylene/diene rubber, butyl rubber, acrylic rubber, polyurethane rubber, fluorine-contained rubber, silicone rubber and epichlorohydrin rubber; and natural rubber, polyurethane resin, silicone resin, and epoxy resin. In the case of using, as the sealing material, the thermoplastic resin, thermosetting resin or mixture thereof, the used resin or mixture is favorably in, e.g., a film form. Such films may be laminated onto each other. The film may be a film including a metal evaporated film in which a metal is evaporated and deposited onto a metal foil piece such as an aluminum foil piece or onto a film as described above.

About the container, any shape may be adopted in accordance with the sealed-type secondary battery in which the container is to be located. As illustrated in, e.g., FIG. 4, the shape to be adopted is preferably a shape about which the length (a) of its upper surface is equal to or longer than the length (b) of its lower surface. In the example illustrated in FIG. 4, a container 5 has a shape about which the length (a) of its upper surface is equal to or longer than the length (b) of its lower surface according to the viewing of a cross section thereof. The container 5 more preferably has a shape satisfying “1≦(a)/(b)≦2”.

In the example illustrated in FIG. 4, a mixture liquid is injected onto the container 5 in the second step. Thereafter, in the third step, a polymer matrix precursor (polyurethane elastomer precursor) inside the container 5 is heated and cured to produce a polymer matrix layer 3 integrated with the container 5. When the polymer matrix layer 3 is made of a polyurethane elastomer containing a magnetic filler, the third step includes a magnetizing step of magnetizing the magnetic filler after the polyurethane elastomer precursor inside the container 5 is heated and cured. In the second step, an opening in the container 5 may be sealed with the same material as used for the container 5, for example, the above-mentioned sealing material after the injection of the mixture liquid into the container 5 and before the curing of the polymer matrix precursor; or the opening in the container 5 may be sealed after the curing of the polymer matrix precursor. When the polymer matrix layer is made of a polyurethane elastomer containing a magnetic filler, the timing when the opening in the container 5 is sealed may be before or after the magnetization of the magnetic filler.

The method for magnetizing the magnetic filler is not particularly limited, and may be performed, using an ordinarily usable magnetizing machine, such as a machine “ES-101100-15SH” manufactured by Denshijiki Industry Co., Ltd. or “TM-YS4E” manufactured by Tamagawa Co., Ltd. Usually, a magnetic field having a magnetic flux density of 1 to 8 T is applied to the filler.

The thickness of the polymer matrix layer 3 is preferably from 100 to 3000 μm, more preferably from 150 to 2000 μm, even more preferably from 200 to 1500 μm. If the thickness is less than 100 μm, the layer 3 becomes brittle at the time of trying to add a necessary amount of the filler into the layer 3, so that the layer 3 tends to be deteriorated in handleability. In the meantime, if the thickness is more than 3000 μm, the polymer matrix layer 3 is excessively compressed not to be easily displaced when located into a gap as described above. Thus, the sensor sensitivity may be lowered.

The magnetic filler in the polymer matrix layer may be evenly dispersed or unevenly dispersed. For the uneven dispersion of the filler, a method is usable which includes: introducing the filler into an elastomer component, and allowing the resultant to stand still at room temperature or a predetermined temperature to precipitate the filler naturally by the weight of the filler. The uneven-dispersion proportion of the filler is adjustable by changing a temperature or period for the standing-still. The filler may be uneven dispersed, using a physical force such as centrifugal force or magnetic force. When the filler is unevenly dispersed, the filler uneven-dispersion proportion in a high-filler-concentration region of the polymer matrix layer, which is a single layer, is preferably more than 50, more preferably 55 or more, even more preferably 60 or more. In this case, the filler uneven-dispersion proportion in a low-filler-concentration region thereof is less than 50. The filler uneven-dispersion proportion in the high-filler-concentration region is 100 at maximum while that in the low-filler-concentration region is 0 at minimum. The polymer matrix layer may be a polymer matrix layer having a structure in which, e.g., two layers are laminated onto each other. In this case, a high-filler-concentration polymer matrix layer may be laminated onto a low-filler-concentration polymer matrix layer, or a polymer matrix layer containing no filler may be laminated onto a polymer matrix layer containing a filler. In the case of laminating two polymer matrix layers onto each other, the filler uneven-dispersion proportion in a high-filler-concentration region of this laminate ranges preferably from 60 to 100 when the filler uneven-dispersion proportion in the whole of the laminate is regarded as 100. Whether the displacement detection sensor uses the case of dispersing the filler unevenly in the single polymer matrix layer, or the case of the laminated polymer matrix layer in which the filler is unevenly dispersed, it is preferred to locate the polymer matrix layer to bring a high-filler-concentration region thereof into contact with the sealed-type secondary battery including one or more cells about which a displacement is to be detected since the sensor is heightened in detection sensitivity.

The filler uneven-dispersion proportion is measured by the following method: A scanning electron microscopy and energy dispersive X-ray analyzing spectrometer (SEM-EDS) is used to observe a cross section of the polymer matrix layer at a magnifying power of 60. About each of the entire region of the cross section in the thickness direction thereof, and four regions obtained by quadrisecting the cross section in the thickness direction, the existing amount of a metal element inherent in the filler (for example, an Fe element in the case of the magnetic filler in the present embodiment) is gained by elementary analysis. In connection with the resultant existing amounts, the ratio of the element existing amount in one of both-side regions of the cross section to that in the entire region in the thickness direction is calculated out. This ratio is defined as the filler uneven-dispersion proportion in the one side region. The filler uneven-dispersion proportion in the other side region is also gained in the same way as described above.

The polymer matrix layer 3 may be a non-foamed body, which contains air bubbles. This layer may be a foamed body, which contains air bubbles, to heighten the sensor in stability and sensitivity and further lighten the sensor. The foamed body may be generally a resin foam. It is preferred to use a thermosetting resin foam, considering compressive permanent set and other properties thereof. Examples of the thermosetting resin foam include a polyurethane resin foam, and a silicone resin foam. Out of these foams, a polyurethane resin foam is preferred. For the polyurethane resin foam, the above-mentioned isocyanate component and active-hydrogen-containing compound are usable.

As a catalyst used for the polyurethane resin foam, a known catalyst is usable without receiving any restriction. Examples thereof include tertiary amine catalysts, such as triethylenediamine (1,4-diazabicyclo[2,2,2]octane), N,N,N′-N′-tetramethylhexanediamine, and bis(2-dimethylaminoethyl) ether); and metal catalysts such as tin octylate, lead octylate, zinc octylate, and bismuth octylate. These catalysts may be used singly or in any combination of two or more thereof.

Examples of a commercially available product of the catalyst include products “TEDA-L33” manufactured by Tosoh Corp., “NIAX CATALYST A1” manufactured by Momentive Performance Materials Inc., “KAORISER NO. 1” and “KAORISER NO. 30P” manufactured by Kao Corp., “DABCO T-9” manufactured by Air Products Industry Co., Ltd., “BTT-24” manufactured by Toei Chemical Industry Co., Ltd., and “PUCAT 25” manufactured by Nihon Kagaku Sangyo Co., Ltd.

A foam stabilizer used for the polyurethane resin foam may be a foam stabilizer used to produce any ordinary polyurethane resin foam, for example, a silicone foam stabilizer, and a fluorine-containing foam stabilizer. A silicone surfactant or fluorine-containing surfactant used as the silicone foam stabilizer or fluorine-containing foam stabilizer has, in the molecule thereof, a moiety soluble in polyurethane-type material, and a moiety insoluble therein. The insoluble moiety causes polyurethane-type material to be evenly dispersed to lower the polyurethane-type material in surface tension, thereby generating air bubbles easily and not breaking the bubbles easily. Of course, if the surface tension is excessively lowered, air bubbles are not easily generated. When, for example, the silicone surfactant is used in the resin foam in the present invention, its dimethylpolysiloxane structure as the insoluble moiety makes it possible to make the diameter of the air bubbles small, and make the number of the air babbles large.

Examples of a commercially available product of the silicone foam stabilizer include products “SF-2962”, “SRX 274DL”, “SF-2965”, “SF-2904”, “SF-2908”, “SF-2904”, and “L5340” each manufactured by Dow Corning Toray Co., Ltd.; and “TEGOSTABs (registered trademark) B8017, 8-8465 and B-8443” manufactured by Evonik Degussa GmbH. Examples of a commercially available product of the fluorine-containing surfactant include products “FC430” and “FC4430” manufactured by 3M; and “FC142D”, “F552”, “F554”, “F558”, “F561”, and “R41” manufactured by DIC Corp.

The blend amount of the foam stabilizer is preferably from 1 to 15 parts by mass, more preferably from 2 to 12 parts by mass for 100 parts by mass of the resin component (s). If the blend amount of the foam stabilizer is less than 1 part by mass, air bubbles are not sufficiently generated. If the amount is more than 25 parts by mass, the foam stabilizer may bleed out.

The bubble content in the foam constituting the polymer matrix layer 3 is preferably from 20 to 80% by volume. When the bubble content is 20% by volume or more, the polymer matrix layer 3 is soft to be easily displaced to heighten the sensor sensitivity favorably. When the bubble content is 80% by volume or less, the polymer matrix layer 3 is restrained from becoming brittle to be heightened in handleability and stability. The bubble content is calculated out by measuring the specific gravity of the layer 3 in accordance with JIS Z-8807-1976, and using this value and the specific gravity value of the non-foamed body.

The average bubble diameter of the foamed body constituting the polymer matrix layer 3 is preferably from 50 to 300 μm. The average opening diameter thereof is preferably from 15 to 100 μm. If the average bubble diameter is less than 50 μm or the average opening diameter is less than 15 μm, the amount of the foam stabilizer tends to increase to deteriorate the stability of properties of the sensor. If the average bubble diameter is more than 300 μm or the average opening diameter is more than 100 μm, the sensor tends to be decreased in contact area with a detection target, such as a cell, to be lowered in stability. The average bubble diameter and the average opening diameter are obtained by observing a cross section of the polymer matrix layer through an SEM at a magnifying power of 60, using an image analysis software to measure, about the resultant image, the respective bubble diameters of all bubbles present inside any area of the cross section and the respective opening diameters of all open bubble-cells inside the same area, and then calculating the respective average values of the bubble diameters and the opening diameters.

The closed bubble-cell proportion in the foamed body constituting the polymer matrix layer 3 is preferably from 5 to 70%. This case makes it possible that the polymer matrix layer 3 exhibits an excellent stability while ensuring good compressibility. Moreover, the filler proportion by volume in the foamed body constituting the polymer matrix layer 3 is preferably from 1 to 30% by volume.

The above-mentioned polyurethane resin foam can be produced by an ordinary method for producing a polyurethane resin foam except that the magnetic filler is incorporated thereinto. The method for forming the magnetic-filler-incorporated polyurethane resin foam includes, for example, the following steps (i) to (v):

step (i) of producing an isocyanate-group-containing urethane prepolymer from a polyisocyanate component and an active hydrogen component;

primary stirring step (ii) of mixing the isocyanate-group-containing urethane prepolymer, a foam stabilizer, a catalyst, and a magnetic filler with each other, stirring the mixture preliminarily, and stirring the mixture vigorously in a nonreactive gas atmosphere in such a manner that the mixture can take in air bubbles;

step (first step) (iii) of adding an active hydrogen component further to the mixture, and stirring the resultant mixture secondarily to prepare a magnetic-filler-containing bubble-dispersed urethane composition;

step (second step) (iv) of injecting the bubble-dispersed urethane composition into a container having a predetermined shape; and

step (third step) (v) of heating and curing the bubble-dispersed urethane composition in the container to produce a urethane resin foam containing the magnetic filler and integrated with the container.

As a method for producing a polyurethane resin foam, known is a chemical foaming method using a reactive foaming agent such as water. It is however preferred to use a mechanical foaming method of stirring, as performed in the steps (ii) and (iii), a mixture containing an isocyanate-group-containing urethane prepolymer, a foam stabilizer, a catalyst and a magnetic filler, and an active hydrogen component mechanically in a nonreactive gas atmosphere. The mechanical foaming method is simpler and easier in material-shaping operation than the chemical foaming method, and does not make use of water as a foaming agent to yield a strong shaped body which has fine bubbles and is excellent in impact resilience (restorability) and others.

Initially, as performed in the step (i), an isocyanate-group-containing urethane prepolymer is produced from a polyisocyanate component and an active hydrogen component. As performed in the primary stirring step (ii), the isocyanate-group-containing urethane prepolymer is mixed with a foam stabilizer, a catalyst, and a magnetic filler. The mixture is preliminarily stirred, and vigorously stirred in a nonreactive gas atmosphere in such a manner that the mixture can take in air bubbles. As performed in the secondary stirring step (iii), an active hydrogen component is further added to the mixture, and the mixture is vigorously stirred to prepare a magnetic-filler-containing bubble-dispersed urethane composition. About a polyurethane resin foam containing a polyisocyanate component, an active hydrogen component and a catalyst, those skilled in the art know a method in which as performed in the steps (i) to (v), an isocyanate-group-containing urethane prepolymer is beforehand produced and then the polyurethane resin foam is formed. Conditions for the production are appropriately selectable in accordance with the blend materials.

About conditions for the production in the step (i), initially, the blend ratio between the polyisocyanate component and the active hydrogen component is selected to set the ratio of isocyanate groups to active hydrogen radicals (“isocyanate groups”/“active hydrogen radicals”) in the polyisocyanate component into a range from 1.5 to 5, preferably from 1.7 to 2.3. The reaction temperature is preferably from 60 to 120° C., and the reaction period is preferably from 3 to 8 hours. Furthermore, a conventionally known urethanizing catalyst or organic catalyst may be used, examples thereof including lead octylate, which is commercially available with a product name “BTT-24” from Toei Chemical Industry Co., Ltd.; and products “TEDA-L33” manufactured by Tosoh Corp., “NIAX CATALYST A1” manufactured by Momentive Performance Materials Inc., “KAORISER NO. 1” manufactured by Kao Corp., and “DABCO T-9” manufactured by Air Products Industry Co., Ltd. An apparatus usable in the step (i) may be an apparatus capable of mixing the above-mentioned materials with each other and stirring the materials under conditions as described above to cause the materials to react with each other. The apparatus may be an apparatus usable for an ordinary polyurethane-production,

The method for performing the primary stirring in the step (ii) may be a method using an ordinary mixing machine capable of mixing a liquid resin with a filler. Examples of the machine include a homogenizer, a dissolver, and a planetary mixer.

It is preferred to add the foam stabilizer into a raw-material-group including the isocyanate-group-containing urethane prepolymer, and then stirring (primarily-stirring) the resultant in the step (ii), and further add the active hydrogen component thereto and then stirring the resultant secondarily in the step (iii) since the bubbles taken into the reaction system are not easily released so that effective foaming can be attained.

The nonreactive gas in the step (ii) is preferably a noncombustible gas. Specific examples thereof include nitrogen, oxygen, carbon dioxide gas, rare gases such as helium and argon; and a mixed gas of two or more of these gases. The nonreactive gas is most preferably air from which water has been removed by drying. Conditions for the primary stirring and the secondary stirring, particularly for the primary stirring, may be the same conditions as used to produce a urethane foam by an ordinary mechanical foaming method. Although the conditions are not particularly limited, stirring blades, or a mixing machine having stirring blades is used to stir the components concerned vigorously at a rotational number of 1000 to 10000 rpm for 1 to 30 minutes. Examples of such a machine include a homogenizer, a dissolver, and a mechanical froth foaming machine.

In the step (v), conditions for the curing are not particularly limited. The conditions are preferably a curing temperature of 60 to 200° C. and a curing period of 10 minutes to 24 hours. If the curing temperature is too high, the resin foam is thermally deteriorated to be made worse in mechanical strength. If the curing temperature is too low, the resin foam is insufficiently cured. If the curing period is too long, the resin foam is thermally deteriorated to be made worse in mechanical strength. If the curing period is too short, the resin foam is insufficiently cured.

The present invention is never limited to the above-mentioned embodiment. The embodiment may be variously modified or changed as far as the modified or changed embodiment does not depart from the subject matter of the invention.

In the above-mentioned embodiment, the following are shown: an example in which the polymer matrix layer 3 is sandwiched in the gap between adjacent two of the cells 2 (see FIG. 2); and an example in which the polymer matrix layer 3 is sandwiched in the gap between one of the cells 2 and the package 11 (see FIG. 3). However, the present invention is not limited, to these examples. For example, a polymer matrix layer may be sandwiched between a package for a battery module included in a battery pack, and a package for a battery module adjacent to the former module, that is, in a gap between respective packages for battery modules adjacent to each other. This case is useful, in particular, for laminated-film-type battery modules. Alternatively, a polymer matrix layer may be sandwiched in a gap between a package for a battery module and a package for a battery pack. Furthermore, a polymer matrix layer may be located inside a cell, or may be located to be sandwiched, for example, between a positive electrode and a separator, between a negative electrode and a separator, between the positive electrode and an external packaging body, between the negative electrode and the external packaging body, or between the separator and the external packaging body. This sensor is useful, in particular, for being used as a displacement detection sensor for a cylindrical or rectangular tube type cell made by winding a positive electrode, a separator and a negative electrode.

In the above-mentioned embodiment, an example is shown in which a change of a magnetic field is used. However, the displacement detection sensor may be configured to use a change of any other external field such as an electrical field. For example, a configuration is conceivable in which a polymer matrix layer contains, as a filler, an electroconductive filler such as metal particles, carbon black or carbon nanotubes, and a detection unit detects a change of an electrical field (resistance change or dielectric constant change) as the external field.

### EXAMPLES

Hereinafter, working examples of the present invention will be described. However, the invention is not limited to these examples.

In order to produce a magnetic polyurethane elastomer which would turn to each polymer matrix layer, the following materials were used:

TDI-80: toluene diisocyanate (COSMONATE T-80, manufactured by Mitsui Chemicals, Inc.; 2,4-bodies: 80%),

Polyol A: polyoxypropylene glycol to which propylene oxide was added, using glycerin as an initiator (EX-3030, manufactured by Asahi Glass Co., Ltd.); OHV: 56; the number of functional groups: 3,

Neodymium based filler: MQP-14-12 (manufactured by Molycorp Magnequench; average particle diameter: 50 μm), and

Bismuth octylate: PUCAT 25 (manufactured by Nihon Kagaku Sangyo Co., Ltd.)

As a prepolymer, prepolymer A was used which is shown in Table 1.

TABLE 1

| | | | A |
|---|---|---|---|
| Prepolymer | TDI-80 | NCO % = 48.3% | 14.8 |
| | Polyol A | 0HV = 56 | 85.2 |

| | |
|---|---|
| NCO % | 3.58 |

### Example 1

Into a reactor were put 85.2 parts by weight of polyol A (polyoxypropylene glycol to which propylene oxide was added, using glycerin as an initiator: EXCENOL 3030, manufactured by Asahi Glass Co., Ltd.; OH value: 56; the number of functional groups: 3). While the polyol was stirred, the polyol was dehydrated under a reduced pressure for 1 hour. Thereafter, the reactor was purged with nitrogen. Next, to the reactor were added 14.8 parts by weight of toluene diisocyanate (COSMONATS T-80, manufactured by Mitsui Chemicals, Inc.; 2,4-bodies: 80%). While the temperature of the inside of the reactor was kept, at 80° C., the reactive components were caused to react with each other for 5 hours to synthesize isocyanate-terminated prepolymer A (NCO %=3.58%).

Next, 675.3 parts by weight of the neodymium based filler (MQP-14-12 manufactured by Molycorp Magnequench; average particle diameter: 50 μm) were added to 0.35 parts by weight of a mixed liquid of 189.4 parts by weight of polyol A and 0.35 parts by weight of bismuth octylate (PUCAT 25, manufactured by Nihon Kagaku Sangyo Co., Ltd.) to prepare a filler dispersed liquid. This filler dispersed liquid was defoamed under a reduced pressure. Thereto were added 100.0 parts by weight of the above-mentioned prepolymer, prepolymer A, defoamed in the same way. These components were mixed with each other and defoamed in a planetary centrifugal mixer (manufactured by Thinky Corp.) to prepare a polyurethane composition (polymer matrix precursor) containing the magnetic filler. This polyurethane composition was injected into a container having a shape (its upper surface: 10 mm; its lower surface: 8.3 mm) (ratio of the upper surface/the lower surface: 1.20; thickness: 1.0 mm) as illustrated in FIG. 4. A doctor blade was used to adjust the thickness thereof into 1.0 mm. This was allowed to stand still at room temperature for 15 minutes (uneven-distribution treating period). Thereafter, the composition was cured at 80° C. for 1 hour to yield a polyurethane resin containing the magnetic filler. Thereafter, its opening surface, i.e., the upper surface was sealed with a polyethylene film to yield a magnetic polyurethane resin in which the entire elastomer was sealed with the polyethylene. A magnetizing machine (manufactured by Benshijiki Industry Co., Ltd.) was used to magnetize the resultant polyurethane resin at 2.0 T to yield a magnetic polyurethane resin integrated with the polyethylene container.

### Example 2

A magnetic polyurethane resin was yielded in the same way as in Example 1 except that the opening surface was sealed not after the polyurethane composition was cured but after the polyurethane composition was injected.

### Examples 3 to 6

Magnetic polyurethane resins were yielded in the same way as in Example 1 except that the ratio of the upper surface to the lower surface was variously changed.

### Comparative Example 1

The same magnetic-filler-containing polyurethane composition was cast into a mold having a spacer of 1.0 mm thickness, and then cured to produce a polyurethane resin containing the magnetic filler. The resin was cut into a size 8.3 mm square. Thereafter, this polyurethane resin was inserted into a polyethylene container having a 10-mm upper surface and an 8.3-mm lower surface (ratio of the upper surface to the lower surface=1.20), and a thickness of 1.0 mm. The upper surface thereof was sealed to yield a magnetic polyurethane resin in which the entire elastomer was sealed.

The magnetic polyurethane resin yielded in each of Examples 1 to 6 and Comparative Example 1 was used to evaluate a change in the magnetic flux density thereof, and the property stability thereof in accordance with the following methods:

### (Magnetic Flux Density Change)

A Hall element (EQ-430L, manufactured by Asahi Kasei Microdevices Corp.) as a detection unit was bonded to a stainless steel plate through a double-sided tape. The produced magnetic polyurethane resin was bonded to the Hall-element-bonded plate from its upper surface. A pressure indenter, 50 mm×50 mm in size, was used to apply pressure thereto. When the bonded resin showed a strain of 10%, a change thereof in magnetic flux density was measured relatively to the state that no pressure was applied to the bonded resin (when the bonded resin showed a strain of 0%).

### (Property Stability Evaluation)

The produced magnetic polyurethane resin integrated with the container was set into a vibration tester, and then sine waves having a vibration frequency of 200 Hz and an amplitude of 0.8 mm (total amplitude: 1.6 mm) were given thereto to make a vibration test. The application of the sine waves was performed for 3 hours from each of three directions perpendicular to each other. A change in the magnetic flux density when the resin showed a strain of 10% between times before and after the vibration test was defined as the property stability of the resin. The number of times of the measurement was set to 10.

TABLE 2

| | | | Ex- | Ex- | Ex- | Ex- | Ex- | Ex- | Compar- |
|---|---|---|---|---|---|---|---|---|---|
| | | | ample | ample | ample | ample | ample | ample | ative |
| | | | 1 | 2 | 3 | 4 | 5 | 6 | Example 1 |
| Blend | Pre- | Prepolmer A | 100.0 | 100.0 | 100.0 | 100.0 | 100.0 | 100.0 | 100.0 |
| | polymer | | | | | | | | |
| | Curing | Polyol A | 189.4 | 189.4 | 189.4 | 189.4 | 189.4 | 189.4 | 189.4 |
| | agent | | | | | | | | |
| | Filler | Neodymium | 675.3 | 675.3 | 675.3 | 675.3 | 675.3 | 675.3 | 675.3 |
| | | type | | | | | | | |
| | | (MQP-14-12) | | | | | | | |
| | Catalyst | Bismuth | 0.35 | 0.35 | 0.35 | 0.35 | 0.35 | 0.35 | 0.35 |
| | | octylate | | | | | | | |

| | | | | | | | | |
|---|---|---|---|---|---|---|---|---|
| | NCO index | 0.45 | 0.45 | 0.45 | 0.45 | 0.45 | 0.45 | 0.45 |
| Production | Container (ratio of | 1.20 | 1.20 | 1.05 | 1.85 | 0.85 | 2.20 | 1.20 |
| conditions | upper surface (a) | | | | | | | |
| | to lower surface (b)) | | | | | | | |
| | Injection of urethane | Done | Done | Done | Done | Done | Done | Not |
| | composition liquid | | | | | | | Done |
| | into container | | | | | | | |
| | Sealing timing | After | After | After | After | After | After | After |
| | | curing | curing | curing | curing | curing | curing | curing |
| Results | Magnetic flux density | 2.7 | 2.5 | 2.4 | 1.8 | 2.1 | 1.4 | 2.0 |
| | change (Gauss) | | | | | | | |
| | Property stability (%) | 7.8 | 9.1 | 8.7 | 9.4 | 12.1 | 10.5 | 14.7 |

The magnetic polyurethane resin according to Comparative Example 1 was a product obtained by inserting the cured elastomer into the container, and was shifted out of position by the vibration to be very bad in property stability. In the meantime, it is understood that the magnetic polyurethane resin, which was integrated with the container, according to each of Examples 1 to 6 was sufficiently large in magnetic flux density change, and was further excellent, in property stability.

### DESCRIPTION OP REFERENCE SIGNS

1: battery module
2: cell
3: polymer matrix layer
4: detection unit
6: container
11: package

1. A method for manufacturing a displacement detection sensor that is for a sealed-type secondary battery and comprises a polymer matrix layer and a detection unit;
the polymer matrix layer comprising a filler which is in a dispersed state and which changes an external field in response to a displacement of the polymer matrix layer, and the detection unit being a unit for detecting a change of the external field; and
the method comprising:
a first step of mixing the filler with a polymer matrix precursor to prepare a mixture liquid,
a second step of injecting the mixture liquid into a container having a predetermined shape, and
a third step of heating and curing the polymer matrix precursor in the container to produce the polymer matrix layer integrated with the container.

2. The method for manufacturing a displacement detection sensor for a sealed-type secondary battery according to claim 1, wherein the polymer matrix layer comprises a magnetic filler as the filler,
the detection unit is a unit for detecting a change of a magnetic field as the external field, and
the third step comprises a magnetizing step of heating and curing the polymer matrix precursor in the container, and subsequently magnetizing the magnetic filler.

3. The method for manufacturing a displacement detection sensor for a sealed-type secondary battery according to claim 1, wherein the container comprises a sealing material.

4. The method for manufacturing a displacement detection sensor for a sealed-type secondary battery according to claim 1, wherein the container has a shape about which the length (a) of its upper surface is equal to or longer than the length (b) of its lower surface.

5. The method for manufacturing a displacement detection sensor for a sealed-type secondary battery according to claim 4, wherein the following is satisfied: 1≦(a)/(b)≦2.

6. A displacement detection sensor that is for a sealed-type secondary battery and is manufactured by the manufacturing method recited in claim 1.

7. A sealed-type secondary battery to which the displacement detection sensor recited in claim 6 is fitted.

8. A method for detecting a displacement of a sealed-type secondary battery;
a polymer matrix layer being set into the sealed-type secondary battery, or being set to the sealed-type secondary battery to contact the secondary battery;
the polymer matrix layer being a layer that comprises a filler which is in a dispersed state and which changes an external field in response to a displacement of the polymer matrix layer, and that is manufactured through at least a first step of mixing the filler with a polymer matrix precursor to prepare a mixture liquid, a second step of injecting the mixture liquid into a container having a predetermined shape, and a third step of heating and curing the polymer matrix precursor in the container to produce the polymer matrix layer integrated with the container; and
the displacement detecting method being a method of detecting the change of the external field, which follows the displacement of the polymer matrix layer, and then detecting the displacement of the sealed-type secondary battery on the basis of the change of the external field.

9. The method for detecting a displacement of a sealed-type secondary battery according to claim 8, wherein the polymer matrix layer comprises a magnetic filler as the filler, and
the third step comprises a magnetizing step of heating and curing the polymer matrix precursor in the container, and subsequently magnetizing the magnetic filler.
